(19) United States
(12) Patent Application Publication
(10) Pub. No.: US 2023/0072220 A1
(43) Pub. Date: Mar. 9, 2023

(54) MULTILAYER-REFLECTIVE-FILM-EQUIPPED SUBSTRATE, REFLECTIVE MASK BLANK, REFLECTIVE MASK, AND METHOD FOR PRODUCING SEMICONDUCTOR DEVICE

(71) Applicant: HOYA CORPORATION, Tokyo (JP)

(72) Inventors: Masanori NAKAGAWA, Tokyo (JP); Kota SUZUKI, Tokyo (JP); Takashi UCHIDA, Tokyo (JP)

(73) Assignee: HOYA CORPORATION, Tokyo (JP)

(21) Appl. No.: 17/793,329

(22) PCT Filed: Mar. 11, 2021
(86) PCT No.: PCT/JP2021/009738

§ 371 Date: Jul. 15, 2022

(30) Foreign Application Priority Data
Mar. 27, 2020 (JP) 2020-058487

(51) Int. Cl. G03F 1/24; G03F 1/52

(52) U.S. Cl. CPC G03F 1/24; G03F 1/52

(57) ABSTRACT

Provided is a substrate with a multilayer reflective film capable of sufficiently reducing a reflectance of the multilayer reflective film with respect to EUV exposure light and preventing occurrence of a phenomenon in which a surface of a protective film on the multilayer reflective film swells and a phenomenon in which the protective film peels off.

A substrate with a multilayer reflective film 110 comprises a multilayer reflective film 5 and a protective film 6 in this order on a main surface of a substrate 1. The substrate 1 contains silicon, titanium, and oxygen as main components, and further contains hydrogen. The multilayer reflective film 5 has a structure in which a low refractive index layer and a high refractive index layer are alternately layered. The multilayer reflective film 5 comprises hydrogen. Hydrogen in the multilayer reflective film 5 has an atomic number density of 7.0×10⁻³ atoms/nm³ or less.

### CROSS-REFERENCE TO RELATED APPLICATIONS

This application is the National Stage of International Application No. PCT/JP2021/009738, filed Mar. 11, 2021, which claims priority to Japanese Patent Application No. 2020-058487, filed Mar. 27, 2020, and the contents of which is incorporated by reference.

### TECHNICAL FIELD

The present disclosure relates to a reflective mask used for manufacturing a semiconductor device and the like, and a substrate with a multilayer reflective film and a reflective mask blank used for manufacturing the reflective mask. The present disclosure also relates to a method for manufacturing a semiconductor device using the reflective mask.

### BACKGROUND ART

An exposure apparatus in semiconductor device manufacturing has developed while gradually shortening the wavelength of a light source. In order to achieve finer pattern transfer, extreme ultra violet (EUV) lithography using EUV (hereinafter also referred to as EUV light) having a wavelength around 13.5 nm has been developed. In the EUV lithography, a reflective mask is used because there are few materials transparent to EUV light. As a typical reflective mask, there are a binary-type reflective mask and a phase shift-type reflective mask (halftone phase shift-type reflective mask). The binary type reflective mask has a relatively thick absorber pattern that sufficiently absorbs EUV light. The phase shift type reflective mask has a relatively thin absorber pattern (phase shift pattern) that reduces EUV light by light absorption and generates reflected light having a phase substantially inverted (phase inverted by approximately 180 degrees) with respect to reflected light from a multilayer reflective film.

Patent Documents 1 to 3 disclose techniques related to such a reflective mask for EUV lithography and a mask blank for manufacturing the reflective mask.

Patent Document 1 describes that a treatment of irradiating a multilayer reflective film in an area outside a mask pattern area with a laser beam or an electron beam to heat the multilayer reflective film is performed. By performing this treatment, diffusion of a high refractive index material and a low refractive index material in the multilayer reflective film proceeds, and a reflectance of the multilayer reflective film with respect to EUV light is reduced.

Patent Document 2 describes TiO₂—SiO₂ glass used in a photomask or the like of EUV lithography. Patent Document 2 describes that the content of hydrogen in the TiO₂—SiO₂ glass is preferably 5×10¹⁷ molecules/cm³ or more. Furthermore, Patent Document 2 also describes that OH is preferably added into the TiO₂—SiO₂ glass.

Patent Document 3 describes that, in a multilayer structure of a silicon layer and a molybdenum layer of a soft X-ray multilayer film reflecting mirror, a hydrogenated layer obtained by hydrogenating silicon is formed at an interface between the silicon layer and the molybdenum layer. Patent Document 3 describes that interaction and diffusion at an interface between the silicon layer and the molybdenum layer can be suppressed by forming the hydrogenated layer.

### PRIOR ART DOCUMENTS

### Patent Documents

Patent Document 1: WO 2010/026998 A
Patent Document 2: JP 2011-162359 A
Patent Document 3: JP H05-297194 A

### Summary of Disclosure

### Technical Problem

In the EUV lithography, a projection optical system including a large number of reflecting mirrors is used due to light transmittance. EUV light is made obliquely incident on the reflective mask to cause these reflecting mirrors not to block projection light (exposure light). At present, an incident angle of 6 degrees with respect to a vertical plane of a reflective mask substrate is the mainstream.

In the EUV lithography, since exposure light is obliquely incident, there is an inherent problem called a shadowing effect. The shadowing effect is a phenomenon in which exposure light is obliquely incident on an absorber pattern having a three-dimensional structure to form a shadow and the dimension and position of a transferred and formed pattern change. The three-dimensional structure of the absorber pattern serves as a wall to form a shadow on a shade side, and the dimension and position of the transferred and formed pattern change. For example, there are differences in the dimension and position of a transfer pattern between a case where the orientation of the absorber pattern to be formed is parallel to a direction of obliquely incident light and a case where the orientation of the absorber pattern to be formed is perpendicular to the direction of the obliquely incident light, which decreases transfer accuracy.

In the reflective mask, it is required to reduce the above shadowing effect due to a demand for ultrafine and highly accurate pattern formation. Therefore, in the reflective mask, it is studied to reduce the film thickness of a thin film pattern (absorber pattern or phase shift pattern). However, it is difficult to avoid that a reflectance with respect to EUV light becomes higher than that in a conventional case by reducing the film thickness of the thin film pattern.

In general, pattern transfer in EUV lithography is performed by step-and-scan of a transfer pattern of a reflective mask onto a transfer target object. In this step-and-scan, by repeating exposure transfer and step movement, a plurality of the same transfer patterns is exposure-transferred onto the transfer target object. At this time, the plurality of transfer patterns is exposure-transferred onto the transfer target object with almost no interval. Therefore, exposure is performed while reflected light from an outer peripheral area of an area where the thin film transfer pattern of the reflective mask is formed is superposed, that is, a so-called superposing exposure state is obtained. If a reflectance of the thin film pattern is higher than that in a conventional case, unnecessary photosensitization may occur in an area where the superposing exposure occurs in the transfer target object.

The present inventors have attempted the method disclosed in Patent Document 1 in order to reduce a reflectance of an outer peripheral area of an area where a transfer pattern of a reflective mask is formed with respect to EUV light. Specifically, a laser beam irradiating treatment was performed to promote diffusion between a constituent element of a low refractive index layer and a constituent element of a high refractive index layer in a multilayer reflective film. As a result of this treatment, it has been newly found that a phenomenon in which a surface of a protective film on the multilayer reflective film swells and a phenomenon in which the protective film peels off may occur. It has also been found that these phenomena may occur even in a case where an electron beam irradiating treatment or a heating treatment is performed. When these phenomena occur, the treatment of promoting diffusion between the constituent element of the low refractive index layer and the constituent element of the high refractive index layer in the multilayer reflective film cannot be continued any more, and a reflectance of the multilayer reflective film with respect to EUV exposure light cannot be sufficiently reduced, which has been a problem. In addition, there is also a problem that dust is generated by rupture of the protective film, and many defects occur in a manufactured reflective mask.

Therefore, an aspect of the present disclosure is to provide a substrate with a multilayer reflective film capable of sufficiently reducing a reflectance of the multilayer reflective film with respect to EUV exposure light and preventing occurrence of a phenomenon in which a surface of a protective film on the multilayer reflective film swells and a phenomenon in which the protective film peels off.

Another aspect of the present disclosure is to provide a reflective mask blank and a reflective mask manufactured using the substrate with a multilayer reflective film, and a method for manufacturing a semiconductor device using the reflective mask.

### Solution to Problem

As a result of intensive studies, the present inventors have found that hydrogen present in a multilayer reflective film turns into a gas by heat generation in the multilayer reflective film due to irradiation with a laser beam or the like, and accumulates at an interface between the multilayer reflective film and a protective film in order to be separated from the multilayer reflective film, thereby causing a phenomenon in which the protective film floats from the multilayer reflective film. Furthermore, the present inventors have also found that a phenomenon occurs in which a hydrogen gas trapped between the multilayer reflective film and the protective film is thermally expanded by a temperature rise of the multilayer reflective film and the protective film to rupture the protective film.

On the other hand, it has been found that hydrogen and an OH group are contained in a substrate of a mask blank for manufacturing a reflective mask, and the hydrogen and the OH group cannot be eliminated. In addition, it has also been found that a phenomenon occurs in which hydrogen and an OH group move from the substrate to the multilayer reflective film, and it is difficult to prevent the phenomenon. Based on these findings, the present inventors made further intensive studies, and as a result, have concluded that the above technical problems can be solved by using a substrate with a multilayer reflective film having any one of the following configurations.

### Configuration 1

A substrate with a multilayer reflective film, comprising the multilayer reflective film and a protective film in this order on a main surface of the substrate, in which

the substrate comprises silicon, titanium, and oxygen as main components, and further comprises hydrogen,

the multilayer reflective film has a structure in which a low refractive index layer and a high refractive index layer are alternately layered, and

the multilayer reflective film comprises hydrogen, and the hydrogen in the multilayer reflective film has an atomic number density of 7.0×10⁻³ atoms/nm³ or less.

### Configuration 2

The substrate with a multilayer reflective film according to configuration 1, in which the high refractive index layer comprises silicon, and the low refractive index layer comprises molybdenum.

### Configuration 3

The substrate with a multilayer reflective film according to configuration 1 or 2, in which hydrogen in the substrate has an atomic number density of 1.0×10¹⁹ atoms/cm³ or more, the atomic number density being obtained by performing analysis on the substrate by secondary ion mass spectrometry.

### Configuration 4

The substrate with a multilayer reflective film according to any one of configurations 1 to 3, in which the protective film comprises ruthenium.

### Configuration 5

The substrate with a multilayer reflective film according to any one of configurations 1 to 4, in which the multilayer reflective film has a mixed area in which a constituent element of the low refractive index layer and a constituent element of the high refractive index layer are mixed on a main surface, and a surface reflectance of the mixed area with respect to EUV light is lower than a surface reflectance of the other area with respect to EUV light.

### Configuration 6

A mask blank comprising a multilayer reflective film, a protective film, and a pattern forming thin film in this order on a main surface of a substrate, in which

the substrate comprises silicon, titanium, and oxygen as main components, and further comprises hydrogen,

the multilayer reflective film has a structure in which a low refractive index layer and a high refractive index layer are alternately layered, and

the multilayer reflective film comprises hydrogen, and the hydrogen in the multilayer reflective film has an atomic number density of 7.0×10⁻³ atoms/nm³ or less.

### Configuration 7

The mask blank according to configuration 6, in which the high refractive index layer comprises silicon, and the low refractive index layer comprises molybdenum.

### Configuration 8

The mask blank according to configuration 6 or 7, in which hydrogen in the substrate has an atomic number density of 1.0×10¹⁹ atoms/cm³ or more, the atomic number density being obtained by performing analysis on the substrate by secondary ion mass spectrometry.

### Configuration 9

The mask blank according to any one of configurations 6 to 8, in which the protective film comprises ruthenium.

### Configuration 10

The mask blank according to any one of configurations 6 to 9, in which the multilayer reflective film has a mixed area in which a constituent element of the low refractive index layer and a constituent element of the high refractive index layer are mixed on a main surface, and a surface reflectance of the mixed area with respect to EUV light is lower than a surface reflectance of the pattern forming thin film with respect to EUV light.

### Configuration 11

A reflective mask comprising a multilayer reflective film, a protective film, and a thin film pattern in this order on a main surface of a substrate, in which

the substrate comprises silicon, titanium, and oxygen as main components, and further comprises hydrogen,

the multilayer reflective film has a structure in which a low refractive index layer and a high refractive index layer are alternately layered,

the multilayer reflective film comprises hydrogen, and the hydrogen in the multilayer reflective film has an atomic number density of 7.0×10⁻³ atoms/nm³ or less, and

the multilayer reflective film has a mixed area in which a constituent element of the low refractive index layer and a constituent element of the high refractive index layer are mixed in an outer peripheral area of an area where a thin film pattern is formed on a main surface, and a surface reflectance of the mixed area with respect to EUV light is lower than a surface reflectance of the thin film pattern with respect to EUV light.

### Configuration 12

The reflective mask according to configuration 11, in which the high refractive index layer comprises silicon, and the low refractive index layer comprises molybdenum.

### Configuration 13

The reflective mask according to configuration 11 or 12, in which hydrogen in the substrate has an atomic number density of 1.0×10¹⁹ atoms/cm³ or more, the atomic number density being obtained by performing analysis on the substrate by secondary ion mass spectrometry.

### Configuration 14

The reflective mask according to any one of configurations 11 to 13, in which the protective film comprises ruthenium.

### Configuration 15

A method for manufacturing a semiconductor device, the method comprising exposure-transferring a transfer pattern onto a resist film on a semiconductor substrate using the reflective mask according to any one of configurations 11 to 14.

### Advantageous Effects of Disclosure

The present disclosure can provide a substrate with a multilayer reflective film capable of sufficiently reducing a reflectance of the multilayer reflective film with respect to EUV exposure light and preventing occurrence of a phenomenon in which a surface of a protective film on the multilayer reflective film swells and a phenomenon in which the protective film peels off.

In addition, the present disclosure can provide a reflective mask blank and a reflective mask each partially having a configuration similar to that of the substrate with a multilayer reflective film, and a method for manufacturing a semiconductor device using the reflective mask.

### BRIEF DESCRIPTION OF DRAWINGS

FIG. 1 is a schematic cross-sectional view of an example of a substrate with a multilayer reflective film.

FIG. 2 is a schematic cross-sectional view of an example of a reflective mask blank.

FIGS. 3A-3E is a process diagram illustrating a method for manufacturing a reflective mask in a schematic cross-sectional view.

### DESCRIPTION OF EMBODIMENTS

Hereinafter, an embodiment of the present disclosure will be specifically described with reference to the drawings. Note that the following embodiment is a mode for specifically describing the present disclosure and does not limit the scope of the present disclosure.

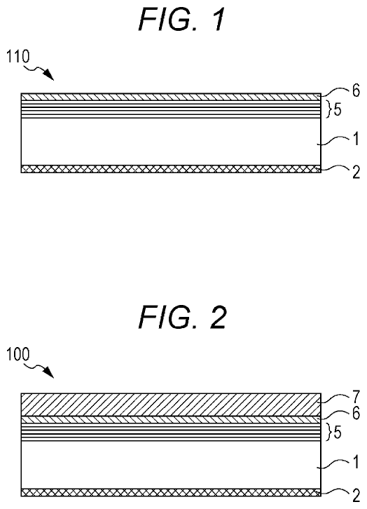

FIG. 1 is a schematic cross-sectional view of a substrate with a multilayer reflective film 110 of the present embodiment. As illustrated in FIG. 1, the substrate with a multilayer reflective film 110 of the present embodiment includes a multilayer reflective film 5 and a protective film 6 in this order on a substrate 1. The multilayer reflective film 5 is a film for reflecting exposure light, and is constituted by a multilayer film in which a low refractive index layer and a high refractive index layer are alternately layered. The protective film 6 is a film for protecting the multilayer reflective film 5 from damage due to dry etching and cleaning in a process of manufacturing a reflective mask 200 described later. The protective film 6 can also protect the multilayer reflective film 5 when a black defect in a mask pattern is corrected using an electron beam (EB). The substrate with a multilayer reflective film 110 of the present embodiment may include a conductive back film 2 on a back surface (main surface opposite to a main surface on which the multilayer reflective film 5 is formed) of the substrate 1.

A reflective mask blank 100 can be manufactured using the substrate with a multilayer reflective film 110 of the present embodiment. FIG. 2 is a schematic cross-sectional view of an example of the reflective mask blank 100. As illustrated in FIG. 2, the reflective mask blank 100 further includes an absorber film (pattern forming thin film) 7 on the protective film 6. By using the reflective mask blank 100 of the present embodiment, it is possible to obtain the reflective mask 200 having the multilayer reflective film 5 having a high reflectance with respect to EUV light.

In the present specification, “having a film B on a film A” includes not only a case where the film B is in contact with a surface of the film A but also a case where another film is present between the film A and the film B. In addition, in the present specification, for example, “a film B is in contact with a surface of a film A” means that the film B is in contact with a surface of the film A without another film interposed between the film A and the film B.

<Substrate with a Multilayer Reflective Film 110>

Hereinafter, the substrate with a multilayer reflective film 110 of the present embodiment will be described in detail. The substrate with a multilayer reflective film 110 includes the substrate 1, the multilayer reflective film 5, and the protective film 6.

<<Substrate 1>>

The substrate 1 contains silicon, titanium, and oxygen as main components, and further contains hydrogen. Hydrogen in this case includes hydrogen contained in a state of an OH group. Examples of the substrate 1 containing silicon, titanium, and oxygen as main components include SiO₂—TiO₂-based glass. The SiO₂—TiO₂-based glass is silica glass containing TiO₂, and is a low thermal expansion material having a thermal expansion coefficient smaller than that of quartz glass. In a case where the substrate 1 is the SiO₂—TiO₂-based glass, the substrate 1 contains hydrogen and an OH group.

Hydrogen in the substrate 1 has an atomic number density of preferably 1.0×10¹⁹ atoms/cm³ or more, more preferably 2.0×10¹⁹ atoms/cm³ or more, the atomic number density being obtained by performing analysis on the substrate 1 by secondary ion mass spectrometry (SIMS). Meanwhile, the atomic number density of hydrogen in the substrate 1 is preferably 5.0×10²¹ atoms/cm³ or less, and more preferably 3.0×10²¹ atoms/cm³ or less. If the content of hydrogen in the substrate 1 is too large, the amount of hydrogen released from the substrate 1 is large, and a large amount of the hydrogen is taken into the multilayer reflective film 5. Note that hydrogen in the substrate 1 detected by analysis by SIMS includes hydrogen in a state of being bonded to Si, hydrogen in a state of an OH group, hydrogen in a state of being present as an ion, hydrogen in a state of being present as a molecule, and the like. Therefore, the numerical value of the atomic number density of hydrogen in the substrate 1 measured by analysis by SIMS includes hydrogen in an OH group.

An OH group in the substrate 1 has a concentration of preferably 50 ppm or more, more preferably 60 ppm or more. The concentration of an OH group in the substrate 1 can be measured by a known method, and for example, can be measured by the method described in JP 4792705 B2.

A first main surface of the substrate 1 on a side where the multilayer reflective film 5 is formed is preferably subjected to surface processing so as to have a predetermined flatness from a viewpoint of enhancing pattern transfer accuracy. In a case of EUV exposure, an area having a size of 132 mm×132 mm of the main surface on a side of the substrate 1 where a transfer pattern is formed has a flatness of preferably 0.1 μm or less, more preferably 0.05 μm or less, still more preferably 0.03 μm or less. In addition, a second main surface (back surface) on a side opposite to the side where the multilayer reflective film 5 is formed is attracted by electrostatic chuck when a reflective mask is set in an exposure apparatus. An area having a size of 142 mm×142 mm of the second main surface has a flatness of preferably 0.1 μm or less, more preferably 0.05 μm or less, still more preferably 0.03 μm or less.

In addition, a high surface smoothness of the substrate 1 is also important. The first main surface of the substrate 1 has a surface roughness of preferably 0.15 nm or less, more preferably 0.10 nm or less in terms of root mean square roughness (Rms). Note that the surface smoothness can be measured with an atomic force microscope.

Furthermore, the substrate 1 preferably has a high rigidity in order to prevent deformation due to a film stress of a film (such as the multilayer reflective film 5) formed on the substrate 1. In particular, the substrate 1 preferably has a high Young's modulus of 65 GPa or more.

<<Multilayer Reflective Film 5>>

The multilayer reflective film 5 imparts a function of reflecting EUV light in the reflective mask 200. The multilayer reflective film 5 is a multilayer film in which layers containing elements having different refractive indices as main components are periodically layered.

In general, as the multilayer reflective film 5, a multilayer film is used in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods (pairs).

The multilayer reflective film 5 includes a stack of “high refractive index layer/low refractive index layer” in which the high refractive index layer and the low refractive index layer are layered in this order from the substrate 1 side. With one “high refractive index layer/low refractive index layer” as one period, this stack may be built up for a plurality of periods. Alternatively, the multilayer reflective film 5 includes a stack of “low refractive index layer/high refractive index layer” in which the low refractive index layer and the high refractive index layer are layered in this order from the substrate 1 side. With one “low refractive index layer/high refractive index layer” as one period, this stack may be built up for a plurality of periods. Note that a layer of the outermost surface of the multilayer reflective film 5, that is, a surface layer of the multilayer reflective film 5 on a side opposite to the substrate 1 is preferably the high refractive index layer. In a case where the high refractive index layer and the low refractive index layer are built up in this order from the substrate 1 side, the low refractive index layer forms the uppermost layer. In this case, the low refractive index layer forms the outermost surface of the multilayer reflective film 5. Therefore, the outermost surface of the multilayer reflective film 5 is easily oxidized and a reflectance of the reflective mask 200 is reduced. Therefore, it is preferable to further form the high refractive index layer on the low refractive index layer forming the uppermost layer. Meanwhile, in a case where the low refractive index layer and the high refractive index layer are built up in this order from the substrate 1 side, the high refractive index layer forms the uppermost layer. In this case, it is not necessary to further form the high refractive index layer.

As the high refractive index layer, for example, a material containing silicon (Si) can be used. As the material containing Si, a Si compound containing Si and at least one element selected from the group consisting of boron (B), carbon (C), zirconium (Zr), nitrogen (N), and oxygen (O) can be used in addition to a Si simple substance. By using the high refractive index layer containing Si, the reflective mask 200 having an excellent reflectance with respect to EUV light can be obtained.

As the low refractive index layer, for example, at least one metal simple substance selected from the group consisting of molybdenum (Mo), ruthenium (Ru), rhodium (Rh), and platinum (Pt), or an alloy thereof can be used.

In the substrate with a multilayer reflective film 110 of the present embodiment, the low refractive index layer is preferably a layer containing molybdenum (Mo), and the high refractive index layer is preferably a layer containing silicon (Si). For example, as the multilayer reflective film 5 for reflecting EUV light having a wavelength of 13 nm to 14 nm, a Mo/Si periodic layered film in which a layer containing Mo and a layer containing Si are alternately layered for about 40 to 60 periods is preferably used.

Note that, in a case where the high refractive index layer forming the uppermost layer of the multilayer reflective film 5 is a layer containing silicon (Si), a silicon oxide layer containing silicon and oxygen may be formed between the uppermost layer (layer containing Si) and the protective film 6. In this case, mask cleaning resistance can be improved.

In the substrate with a multilayer reflective film 110 of the present embodiment, the multilayer reflective film 5 contains hydrogen. Hydrogen in the multilayer reflective film 5 has an atomic number density of 7.0×10⁻³ atoms/nm³ or less, preferably 6.5×10⁻³ atoms/nm³ or less, more preferably 6.0×10⁻³ atoms/nm³ or less. Meanwhile, the atomic number density of hydrogen in the multilayer reflective film 5 is preferably 1.0×10⁻⁴ atoms/nm³ or more, and more preferably 2.0×10⁻⁴ atoms/nm³ or more. The atomic number density of hydrogen in the multilayer reflective film 5 can be measured by, for example, secondary ion mass spectrometry (SIMS).

In general, in a case where the substrate 1 is made of SiO₂—TiO₂-based glass, it is difficult to completely exclude hydrogen and an OH group from the substrate 1 because SiO₂—TiO₂-based glass necessarily contains hydrogen and an OH group in a predetermined amount or more. Therefore, hydrogen and an OH group released from the substrate 1 are also taken into the multilayer reflective film 5 formed on the substrate 1. In particular, in a case where the high refractive index material in the multilayer reflective film 5 is silicon, silicon easily takes in hydrogen, and therefore such a phenomenon remarkably occurs.

It is difficult to make a film stress of the multilayer reflective film 5 zero at the time of film formation. In order to reduce the film stress of the multilayer reflective film 5, a heating treatment is often performed. During this heating treatment, hydrogen and an OH group in the substrate 1 are easily taken into the multilayer reflective film 5. In addition, when a resist film 8 is formed on the absorber film 7 of the mask blank 100 described later, a resist liquid is applied by a spin coating method or the like, and then a heating treatment (pre applied bake (PAB)) for drying the resist liquid is performed. During this heating treatment, hydrogen and an OH group in the substrate 1 are easily taken into the multilayer reflective film 5. Furthermore, in a case where the resist film 8 is a chemically amplified resist, a transfer pattern is exposure-drawn on the resist film 8 with an electron beam, and then a heating treatment (post exposure bake (PEB) is performed. Furthermore, after a development treatment is performed on the resist film 8, a heating treatment (post bake) is also performed. Also during these heating treatments, hydrogen and an OH group in the substrate 1 are easily taken into the multilayer reflective film 5.

In a case where hydrogen and an OH group are taken into the multilayer reflective film 5, a phenomenon occurs in which the hydrogen and the OH group taken into the multilayer reflective film 5 are vaporized and accumulated between the multilayer reflective film 5 and the protective film 6 when the multilayer reflective film 5 is irradiated with a laser or the like to diffuse a constituent element of the low refractive index layer and a constituent element of the high refractive index layer to reduce a reflectance. In this case, since a phenomenon in which the protective film 6 on the multilayer reflective film 5 swells or a phenomenon in which the protective film 6 itself ruptures occurs, there is a problem that laser irradiation or the like cannot be sufficiently performed, and a reflectance of a predetermined area (light shielding area or the like on an outer periphery of a transfer pattern forming area) of the multilayer reflective film 5 with respect to EUV light cannot be sufficiently reduced.

The substrate with a multilayer reflective film 110 of the present embodiment suppresses the atomic number density of hydrogen in the multilayer reflective film 5 within the above range. As a result, when laser irradiation or the like is performed in order to reduce a reflectance of the multilayer reflective film 5, it is possible to suppress occurrence of a phenomenon in which hydrogen taken into the multilayer reflective film 5 is vaporized and accumulated between the multilayer reflective film 5 and the protective film 6. As a result, it is possible to sufficiently reduce the reflectance of the predetermined area (light shielding area or the like on an outer periphery of a transfer pattern forming area) of the multilayer reflective film 5 with respect to EUV light, and it is possible to obtain the substrate with a multilayer reflective film 110 and the reflective mask blank 100 capable of manufacturing a reflective mask with high pattern transfer accuracy.

A reflectance of the multilayer reflective film 5 alone of the present embodiment with respect to EUV light is usually preferably 65% or more. When the reflectance of the multilayer reflective film 5 is 65% or more, the multilayer reflective film 5 can be preferably used as the reflective mask 200 for manufacturing a semiconductor device. An upper limit of the reflectance is usually 73%. Note that the film thicknesses and the number of periods (pairs) of the low refractive index layer and the high refractive index layer constituting the multilayer reflective film 5 can be appropriately selected depending on an exposure wavelength. Specifically, the film thicknesses and the number of periods (pairs) of the low refractive index layer and the high refractive index layer constituting the multilayer reflective film 5 can be selected so as to satisfy the Bragg reflection law. In the multilayer reflective film 5, there are a plurality of high refractive index layers and a plurality of low refractive index layers, but the film thickness does not need to be the same between the high refractive index layers and between the low refractive index layers. In addition, the film thickness of the outermost surface (for example, a Si layer) of the multilayer reflective film 5 can be adjusted within a range that does not reduce the reflectance. The film thickness of the high refractive index layer (for example, a Si layer) forming the outermost surface is, for example, 3 nm to 10 nm.

In the substrate with a multilayer reflective film 110 of the present embodiment, the multilayer reflective film 5 preferably includes 30 to 60 periods (pairs), more preferably 35 to 55 periods (pairs), and still more preferably 35 to 45 periods (pairs) with one pair of the low refractive index layer and the high refractive index layer as one period (pair). As the number of periods (the number of pairs) is larger, a higher reflectance can be obtained, but time for forming the multilayer reflective film 5 is longer. By setting the number of periods of the multilayer reflective film 5 within an appropriate range, the multilayer reflective film 5 having a relatively high reflectance can be obtained in a relatively short time.

The multilayer reflective film 5 of the present embodiment can be formed by a sputtering method such as an ion beam sputtering method, a DC sputtering method, or an RF sputtering method. The multilayer reflective film 5 is preferably formed by an ion beam sputtering method from viewpoints that impurities are hardly mixed in the multilayer reflective film 5, an ion source is independent and condition setting is relatively easy, and the like.

The multilayer reflective film 5 of the present embodiment has a film stress of preferably 0.42 GPa or less, more preferably 0.25 GPa or less. It is difficult to cause the multilayer reflective film 5 to have a film stress equal to or less than the above film stress at a stage where the multilayer reflective film 5 is formed, and the film stress is often reduced by performing a heating treatment or the like as described above.

<<Protective Film 6>>

The protective film 6 can be formed on the multilayer reflective film 5 or in contact with a surface of the multilayer reflective film 5 in order to protect the multilayer reflective film 5 from dry etching and cleaning in a process of manufacturing the reflective mask 200 described later. In addition, the protective film 6 also protects the multilayer reflective film 5 when a black defect of a thin film pattern is corrected using an electron beam (EB). Here, although FIGS. 1 and 2 illustrate a case where the protective film 6 has one layer, the protective film 6 may have a stack of two or more layers. The protective film 6 is made of a material having resistance to an etchant and a cleaning liquid used when the absorber film 7 is patterned. Formation of the protective film 6 on the multilayer reflective film 5 can suppress damage to a surface of the multilayer reflective film 5 when the reflective mask 200 (EUV mask) is manufactured using the substrate 110 having the multilayer reflective film 5 and the protective film 6. Therefore, a reflectance characteristic of the multilayer reflective film 5 with respect to EUV light is improved.

In the reflective mask blank 100 of the present embodiment, a material having resistance to an etching gas used for dry etching for patterning the absorber film 7 formed on the protective film 6 can be selected as a material of the protective film 6.

In a case where the absorber film 7 in contact with a surface of the protective film 6 is a thin film made of a material that can be etched by dry etching with a fluorine-based gas or dry etching with a chlorine-based gas not containing oxygen (for example, in a case of a thin film made of a material containing tantalum (Ta)), for example, a material containing ruthenium as a main component can also be selected as the material of the protective film 6. Examples of the material containing ruthenium as a main component include a Ru metal simple substance, a Ru alloy containing Ru and at least one metal selected from the group consisting of titanium (Ti), niobium (Nb), molybdenum (Mo), zirconium (Zr), yttrium (Y), boron (B), lanthanum (La), cobalt (Co), rhenium (Re), and rhodium (Rh), and a material containing nitrogen in addition to the Ru metal simple substance or the Ru alloy.

In a case where the absorber film 7 in contact with a surface of the protective film 6 is a thin film made of a material containing ruthenium (Ru) and chromium (Cr) (predetermined RuCr-based material), a material selected from the group consisting of a silicon-based material such as silicon (Si), a material containing silicon (Si) and oxygen (O), a material containing silicon (Si) and nitrogen (N), or a material containing silicon (Si), oxygen (O), and nitrogen (N), and a chromium-based material such as chromium (Cr) or a material containing chromium (Cr) and at least one element selected from the group consisting of oxygen (O), nitrogen (N), and carbon (C) can be used as the material of the protective film 6.

In a case where the protective film 6 has a configuration containing ruthenium (Ru) and rhodium (Rh), etching resistance of the protective film 6 to a mixed gas of a chlorine-based gas and an oxygen gas, etching resistance of the protective film 6 to a chlorine-based gas, etching resistance of the protective film 6 to a fluorine-based gas, and sulfuric acid peroxide (SPM) cleaning resistance of the protective film 6 are improved. If the content of rhodium in the protective film 6 is too small, an effect of addition cannot be obtained. If the content of rhodium is too large, an extinction coefficient k of the protective film 6 with respect to EUV light increases, and therefore a reflectance of the reflective mask 200 is reduced. Therefore, the content of rhodium in the protective film 6 is preferably 15 atomic % or more and less than 50 atomic %, and more preferably 20 atomic % or more and 40 atomic % or less.

The protective film 6 can contain at least one selected from the group consisting of N, C, O, H, and B. The protective film 6 preferably further contains nitrogen (N). When the protective film 6 further contains nitrogen (N), crystallinity can be lowered. As a result, since the protection film 6 can be densified, resistance to an etching gas and cleaning can be further enhanced. The content of nitrogen in the protective film 6 is preferably more than 1 atomic % and 20 atomic % or less, and more preferably 3 atomic % or more and 10 atomic % or less.

The protective film 6 preferably further contains oxygen (O). When the protective film 6 further contains oxygen (O), crystallinity can be lowered. As a result, since the protective film 6 can be densified, resistance to an etching gas and cleaning can be further enhanced. The content of oxygen in the protective film 6 is preferably more than 1 atomic % and 20 atomic % or less, and more preferably 3 atomic % or more and 10 atomic % or less.

The film thickness of the protective film 6 is not particularly limited as long as the function as the protective film 6 can be achieved. The film thickness of the protective film 6 is preferably 1.0 nm to 8.0 nm, and more preferably 1.5 nm to 6.0 nm from a viewpoint of the reflectance with respect to EUV light. An extinction coefficient of the protective film 6 is preferably adjusted to 0.030 or less, and more preferably 0.025 or less.

Meanwhile, the protective film 6 may have a configuration including a first layer and a second layer from the substrate 1 side. In this case, the second layer can be a thin film having the above-described configuration containing ruthenium (Ru) and rhodium (Rh).

In order to suppress diffusion of silicon (Si) from the multilayer reflective film 5 to the protective film 6, the first layer of the protective film 6 preferably contains ruthenium (Ru) and at least one selected from the group consisting of magnesium (Mg), aluminum (Al), titanium (Ti), vanadium (V), chromium (Cr), germanium (Ge), zirconium (Zr), niobium (Nb), molybdenum (Mo), rhodium (Rh), hafnium (Hf), and tungsten (W). In particular, in a case where the first layer is a RuTi film, a RuZr film, or a RuAl film, diffusion of silicon (Si) to the protective film 6 can be more reliably suppressed.

The content of Ru in the first layer is preferably more than 50 atomic % and less than 100 atomic %, more preferably 80 atomic % or more and less than 100 atomic %, and particularly preferably more than 95 atomic % and less than 100 atomic %.

In the substrate with a multilayer reflective film 110 of the present embodiment, the content of Ru in the second layer is preferably smaller than the content of Ru in the first layer. For example, in a case where the first layer is a RuTi film and the second layer is a RuRh film, diffusion of silicon (Si) to the protective film 6 can be suppressed even if the content of Ti in the RuTi film of the first layer is relatively low. Therefore, since the content of Ru in the second layer is smaller than the content of Ru in the first layer, resistance to an etching gas and cleaning can be further enhanced, and diffusion of silicon (Si) to the protective film 6 can be suppressed.

A refractive index of the second layer of the protective film 6 is preferably smaller than a refractive index of the first layer. As a result, the substrate with a protective film (the substrate with a multilayer reflective film 110 having the protective film 6) can be manufactured without reducing a reflectance with respect to EUV light from the multilayer reflective film 5 including the protective film 6. The refractive index of the second layer is preferably 0.920 or less, and more preferably 0.885 or less.

The first layer of the protective film 6 has a film thickness of preferably 0.5 nm to 2.0 nm, more preferably 1.0 nm to 1.5 nm. The second layer of the protective film 6 has a film thickness of preferably 1.0 nm to 7.0 nm, more preferably 1.5 nm to 4.0 nm.

In EUV lithography, since there are few substances that are transparent to exposure light, it is not technically easy to apply an EUV pellicle that prevents foreign matters from adhering to a mask pattern surface. For this reason, pellicle-less operation without using a pellicle has been the mainstream. In addition, in EUV lithography, exposure contamination such as carbon film deposition on a mask or oxide film growth due to EUV exposure occurs. Therefore, at a stage where the reflective mask 200 for EUV exposure is used for manufacturing a semiconductor device, it is necessary to frequently clean the mask to remove foreign matters and contamination on the mask. Therefore, the reflective mask 200 for EUV exposure is required to have extraordinary mask cleaning resistance as compared with a transmissive mask for optical lithography. The reflective mask 200 has the protective film 6, whereby cleaning resistance to a cleaning liquid can be enhanced.

As a method for forming the protective film 6, it is possible to adopt a method similar to a known film forming method without any particular limitation. Specific examples thereof include a sputtering method and an ion beam sputtering method.

In the substrate with a multilayer reflective film 110 of the present embodiment, the multilayer reflective film 5 can have a mixed area in which a constituent element of the low refractive index layer and a constituent element of the high refractive index layer are mixed on the first main surface. For example, in a case where the low refractive index layer is a layer containing molybdenum (Mo) and the high refractive index layer is a layer containing silicon (Si), the multilayer reflective film 5 can have a mixed area in which Mo and Si are mixed. Such a mixed area can be formed by partially heating the multilayer reflective film 5. For example, the mixed area can be formed by irradiating the multilayer reflective film 5 with a laser beam to heat the multilayer reflective film 5. In this case, the laser beam may be emitted from above the multilayer reflective film 5, or may be emitted from above the protective film 6 after the protective film 6 is formed on the multilayer reflective film 5. As a light source of the laser beam, for example, a CO₂ laser, a solid laser, or the like can be used. Note that the mixed area may be formed by irradiating the multilayer reflective film 5 with an electron beam.

A surface reflectance of the mixed area with respect to EUV light is lower than a surface reflectance of the other area with respect to EUV light. For example, in a case where the mixed area is formed in an outer peripheral area of an area where a thin film pattern is formed when the reflective mask 200 is manufactured using the substrate with a multilayer reflective film 110, a reflectance of the multilayer reflective film 5 in the outer peripheral area can be made lower than a reflectance of the multilayer reflective film 5 in the other area. As a result, when the reflective mask 200 is set in an exposure apparatus and exposure transfer is performed by step-and-scan, it is possible to prevent occurrence of unnecessary photosensitization due to superposing exposure. As a result, a pattern can be transferred onto a resist film or the like formed on a surface of a semiconductor substrate with higher accuracy. The surface reflectance of the mixed area with respect to EUV light is preferably 1.3% or less, more preferably 1% or less, and still more preferably 0.7% or less.

<Reflective Mask Blank 100>

The reflective mask blank 100 of the present embodiment will be described. By using the reflective mask blank 100 of the present embodiment, it is possible to manufacture the reflective mask 200 having the multilayer reflective film 5 having a high reflectance with respect to exposure light.

<<Absorber Film (Pattern Forming Thin Film) 7>>

The reflective mask blank 100 has the absorber film (pattern forming thin film) 7 on the above-described substrate with a multilayer reflective film 110. That is, the absorber film 7 is formed on the protective film 6 forming the uppermost layer of the substrate with a multilayer reflective film 110. A basic function of the absorber film 7 is to absorb EUV light. The absorber film 7 may be the absorber film 7 for the purpose of absorbing EUV light, or may be the absorber film 7 having a phase shift function in consideration of a phase difference of EUV light. The absorber film 7 having a phase shift function absorbs EUV light and reflects a part of the EUV light to shift a phase of the EUV light. That is, in the reflective mask 200 in which the absorber film 7 having a phase shift function is patterned, in a portion where the absorber film 7 is formed, a part of light is reflected at a level that does not adversely affect pattern transfer while EUV light is absorbed and attenuated. In addition, in an area (field portion) where the absorber film 7 is not formed, EUV light is reflected from the multilayer reflective film 5 via the protective film 6. Therefore, there is a desired phase difference between reflected light from the absorber film 7 having a phase shift function and reflected light from the field portion. The absorber film 7 having a phase shift function is formed such that a phase difference between reflected light from the absorber film 7 and reflected light from the multilayer reflective film 5 is 130 to 230 degrees. Beams of light having a reversed phase difference around 180 degrees interfere with each other at a pattern edge portion to improve an image contrast of a projected optical image. As the image contrast is improved, resolution is increased, and various exposure-related margins such as an exposure margin and a focus margin can be increased.

The absorber film 7 may be a single-layer film or a multilayer film including a plurality of films. In a case of a single layer film, since the number of steps at the time of manufacturing a mask blank can be reduced, production efficiency is improved. In a case of a multilayer film, an upper layer of the absorber film can function as an antireflection film at the time of mask pattern inspection using light. In this case, it is necessary to appropriately set the optical constant and the film thickness of the upper layer of the absorber film. This improves inspection sensitivity at the time of mask pattern inspection using light. In addition, as the upper layer of the absorber film, a film containing oxygen (O), nitrogen (N), and the like that can improve oxidation resistance can be used. This improves temporal stability of the absorber film. As described above, by using the absorber film 7 constituted by a multilayer film, various functions can be imparted to the absorber film 7. In a case where the absorber film 7 has a phase shift function, by using the absorber film 7 constituted by a multilayer film, a range of adjustment on an optical surface can be increased. This makes it easy to obtain a desired reflectance.

As a material of the absorber film 7, a material having a function of absorbing EUV light and capable of being processed by etching or the like (for example, capable of being etched by dry etching with a chlorine (Cl) or fluorine (F)-based gas) can be used. As a material having such a function, a tantalum (Ta) simple substance or a tantalum compound containing Ta as a main component can be preferably used.

The above-described absorber film 7 made of tantalum, a tantalum compound, or the like can be formed by a sputtering method such as a DC sputtering method or an RF sputtering method. For example, the absorber film 7 can be formed by a reactive sputtering method using a target containing tantalum and boron and using an argon gas containing oxygen or nitrogen.

The tantalum compound for forming the absorber film 7 includes an alloy of Ta. In a case where the absorber film 7 is an alloy of Ta, the crystalline state of the absorber film 7 is preferably an amorphous or microcrystalline structure from a viewpoint of smoothness and flatness. If a surface of the absorber film 7 is not smooth or flat, an absorber pattern 7a may have a large edge roughness and poor pattern dimensional accuracy. The absorber film 7 has a surface roughness of preferably 0.5 nm or less, more preferably 0.4 nm or less, still more preferably 0.3 nm or less in terms of root mean square roughness (Rms).

As the tantalum compound for forming the absorber film 7, a compound containing Ta and B, a compound containing Ta and N, a compound containing Ta, O, and N, a compound containing Ta and B and further containing at least either O or N, a compound containing Ta and Si, a compound containing Ta, Si, and N, a compound containing Ta and Ge, a compound containing Ta, Ge, and N, and the like can be used.

Ta has a large absorption coefficient with respect to EUV light. In addition, Ta is a material that can be easily dry-etched with a chlorine-based gas or a fluorine-based gas. Therefore, Ta can be said to be a material having excellent processability to be used for the absorber film 7. By further adding B, Si, and/or Ge, or the like to Ta, an amorphous material can be easily obtained. As a result, the smoothness of the absorber film 7 can be improved. In addition, when N and/or 0 is added to Ta, resistance of the absorber film 7 to oxidation is improved, and therefore temporal stability of the absorber film 7 can be improved.

As the material of the absorber film 7, in addition to tantalum or a tantalum compound, at least one metal selected from the group consisting of palladium (Pd), silver (Ag), platinum (Pt), gold (Au), iridium (Ir), tungsten (W), chromium (Cr), cobalt (Co), manganese (Mn), tin (Sn), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), or a compound thereof can be used.

<<Conductive Back Film 2>>

On the second main surface of the substrate 1 (on a surface opposite to the multilayer reflective film 5), the conductive back film 2 for electrostatic chuck is formed. The conductive back film 2 usually has a sheet resistance of 100 Ω/□ or less. The conductive back film 2 can be formed by, for example, a DC sputtering method, an RF sputtering method, or an ion beam sputtering method using a target of a metal such as chromium or tantalum or an alloy thereof. A material containing chromium (Cr) for forming the conductive back film 2 is preferably a Cr compound containing Cr and at least one selected from the group consisting of boron, nitrogen, oxygen, and carbon. Examples of the Cr compound include CrN, CrON, CrCN, CrCON, CrBN, CrBON, CrBCN, CrBOCN, and the like. A material containing tantalum (Ta) for forming the conductive back film 2 is preferably Ta (tantalum), an alloy containing Ta, or a Ta compound containing either Ta or an alloy containing Ta and at least one selected from the group consisting of boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like.

The film thickness of the conductive back film 2 is not particularly limited, but is usually 10 nm to 200 nm. The conductive back film 2 can adjust a stress of the mask blank 100 on the second main surface side. That is, the conductive back film 2 can balance a stress generated by various films formed on the first main surface side with a stress on the second main surface side. By balancing the stress on the first main surface side with the stress on the second main surface side, the conductive back film 2 can adjust the reflective mask blank 100 so as to be flat.

Note that, before the above-described absorber film 7 is formed, the conductive back film 2 can be formed on the substrate with a multilayer reflective film 110. In this case, the substrate with a multilayer reflective film 110 including the conductive back film 2 as illustrated in FIG. 1 can be obtained.

<Other Thin Films>

The substrate with a multilayer reflective film 110 and the reflective mask blank 100 manufactured by the manufacturing method of the present embodiment can each include an etching hard mask film (also referred to as an “etching mask film”) and/or the resist film 8 on the absorber film 7. Typical examples of a material of the etching hard mask film include silicon (Si), a material containing silicon and at least one element selected from the group consisting of oxygen (O), nitrogen (N), carbon (C), and hydrogen (H), chromium (Cr), a material containing chromium and at least one element selected from the group consisting of oxygen (O), nitrogen (N), carbon (C), and hydrogen (H), and the like. Specific examples thereof include SiO₂, SiON, SiN, SiO, Si, SiC, SiCO, SiCN, SiCON, Cr, CrN, CrO, CrON, CrC, CrCO, CrCN, CrOCN, and the like. However, in a case where the absorber film 7 is a compound containing oxygen, it is better to avoid a material containing oxygen (for example, Sift) as the etching hard mask film from a viewpoint of etching resistance. In a case where the etching hard mask film is formed, the film thickness of the resist film 8 can be reduced, which is advantageous for forming a finer pattern.

In the reflective mask blank 100 of the present embodiment, the multilayer reflective film 5 can have a mixed area in which a constituent element of the low refractive index layer and a constituent element of the high refractive index layer are mixed on the first main surface. The mixed area can be formed, for example, by irradiating the multilayer reflective film 5 with a laser beam to heat the multilayer reflective film 5. In this case, the laser beam may be emitted from above the multilayer reflective film 5, or may be emitted from above the protective film 6 after the protective film 6 is formed on the multilayer reflective film 5. After the absorber film 7 is formed on the protective film 6, a laser beam may be emitted from above the absorber film 7. As a light source of the laser beam, for example, a CO₂ laser, a solid laser, or the like can be used.

A surface reflectance of the mixed area with respect to EUV light is lower than a surface reflectance of the absorber film 7 with respect to EUV light. For example, in a case where the mixed area is formed in an outer peripheral area of an area where a thin film pattern is formed when the reflective mask 200 is manufactured using the reflective mask blank 100, a reflectance of the multilayer reflective film 5 in the outer peripheral area can be made lower than a reflectance of the absorber film 7 in the area where the thin film pattern is formed. As a result, when the reflective mask 200 is set in an exposure apparatus and exposure transfer is performed by step-and-scan, it is possible to prevent occurrence of unnecessary photosensitization due to superposing exposure. As a result, a pattern can be transferred onto a resist film or the like formed on a surface of a semiconductor substrate with higher accuracy.

<Reflective Mask 200>

By patterning the absorber film 7 of the above-described reflective mask blank 100, the reflective mask 200 having the protective film 6 on the multilayer reflective film 5 and having the absorber pattern 7a on the protective film 6 can be obtained. By using the reflective mask blank 100 of the present embodiment, it is possible to obtain the reflective mask 200 having the multilayer reflective film 5 having a high reflectance with respect to exposure light.

A method for manufacturing the reflective mask 200 using the reflective mask blank 100 of the present embodiment will be described. Here, only an outline will be described, and a detailed description will be given below in Examples with reference to the drawings.

The reflective mask blank 100 is prepared, and the resist film 8 is formed on the outermost surface of a first main surface of the reflective mask blank 100 (on the absorber film 7 as described in the following Examples) (this is not necessary in a case where the reflective mask blank 100 includes the resist film 8). A desired pattern such as a circuit pattern is drawn (exposed) on the resist film 8. At this time, in a case where a treatment of forming a mixed area in the multilayer reflective film 5 in an outer peripheral area 204 of an area where a thin film pattern to be a transfer pattern is formed (a treatment by laser irradiation or electron beam irradiation, or the like) is performed in a subsequent step, a pattern in the outer peripheral area 204 may also be drawn (exposed). Furthermore, the resist film 8 is developed and rinsed to form a predetermined resist pattern 8a.

Using the resist pattern 8a as a mask, the absorber film 7 is dry-etched to form the absorber pattern 7a. Note that, as an etching gas, a gas selected from the group consisting of a chlorine-based gas such as Cl₂, SiCl₄, or CHCl₃, a mixed gas containing a chlorine-based gas and O₂ at a predetermined ratio, a mixed gas containing a chlorine-based gas and He at a predetermined ratio, a mixed gas containing a chlorine-based gas and Ar at a predetermined ratio, a fluorine-based gas such as CF₄, CHF₃, C₂F₆, C₃F₆, C₄F₆, C₄F₈, CH₂F₂, CH₃F, C₃F₈, SF₆, or F₂, a mixed gas containing a fluorine-based gas and O₂ at a predetermined ratio, and the like can be used.

Next, the resist pattern 8a is removed by ashing or a resist peeling liquid to form the reflective mask 200.

In the reflective mask 200 of the present embodiment, the multilayer reflective film 5 can have a mixed area in which a constituent element of the low refractive index layer and a constituent element of the high refractive index layer are mixed on the first main surface. The mixed area can be formed, for example, by irradiating the multilayer reflective film 5 with a laser beam to heat the multilayer reflective film 5. In this case, the laser beam may be emitted from above the multilayer reflective film 5, or may be emitted from above the protective film 6 after the protective film 6 is formed on the multilayer reflective film 5. After the absorber film 7 is formed on the protective film 6, a laser beam may be emitted from above the absorber film 7. After the absorber pattern 7a is formed on the absorber film 7, a laser beam may be emitted from above the absorber film 7 in an outer peripheral area of an area where the absorber pattern 7a is formed. As a light source of the laser beam, for example, a CO₂ laser, a solid laser, or the like can be used.

A surface reflectance of the mixed area with respect to EUV light is lower than a surface reflectance of the absorber pattern 7a with respect to EUV light. For example, in a case where the mixed area is formed in the outer peripheral area of the area where the absorber pattern 7a is formed, a reflectance of the multilayer reflective film 5 in the outer peripheral area can be made lower than a reflectance of the absorber pattern 7a. As a result, when the reflective mask 200 is set in an exposure apparatus and exposure transfer is performed by step-and-scan, it is possible to prevent occurrence of unnecessary photosensitization due to superposing exposure. As a result, a pattern can be transferred onto a resist film or the like formed on a surface of a semiconductor substrate with higher accuracy.

Meanwhile, in the substrate with a multilayer reflective film 110, the reflective mask blank 100, and the reflective mask 200, a reference mark may be formed on the multilayer reflective film 5. In general, in a case where a defect is present on the first main surface of the substrate 1, the multilayer reflective film 5, the protective film 6, the absorber film 7, or the like, the reference mark is formed as a reference of position coordinates of the defect. By irradiating the protective film 6 and the multilayer reflective film 5 with high energy light such as a laser beam, the protective film 6 and the multilayer reflective film 5 are shrunk to form a recess, and the recess may be used as the reference mark. In a case where the reference mark is formed by such a method, a phenomenon occurs in which hydrogen and an OH group taken into the multilayer reflective film 5 are vaporized and accumulated between the multilayer reflective film 5 and the protective film 6. In addition, a phenomenon in which the protective film 6 on the multilayer reflective film 5 swells or a phenomenon in which the protective film 6 itself ruptures occurs. By applying the above-described multilayer reflective film 5, the reference mark can be formed without occurrence of these phenomena.

<Method for Manufacturing Semiconductor Device>

A method for manufacturing a semiconductor device according to the present embodiment includes a step of performing a lithography step using an exposure apparatus to exposure-transfer a transfer pattern onto a transfer target object using the above-described reflective mask 200.

By performing EUV exposure using the reflective mask 200 of the present embodiment, a desired transfer pattern can be exposure-transferred onto a resist film on a semiconductor substrate. Through various steps such as etching of a film to be processed, formation of an insulating film or a conductive film, introduction of a dopant, and annealing in addition to this lithography step, it is possible to manufacture a semiconductor device in which a desired electronic circuit is formed at a high yield.

### EXAMPLES

Hereinafter, Examples and Comparative Example will be described with reference to the drawings.

The substrate with a multilayer reflective film 110 of Examples includes the substrate 1, the multilayer reflective film 5, and the protective film 6 as illustrated in FIG. 1.

First, four substrates 1 each having a size of 6025 (about 152 mm×152 mm×6.35 mm) and obtained by cutting out SiO₂—TiO₂ glass ingots having different configurations and polishing first main surfaces and second main surfaces were prepared. These substrates 1 are substrates made of low thermal expansion glass (SiO₂—TiO₂-based glass). The main surfaces of the substrates 1 were polished through a rough polishing step, a precision polishing step, a local processing step, and a touch polishing step.

Next, the multilayer reflective film 5 was formed on a main surface (first main surface) of each of the four substrates 1. The multilayer reflective film 5 formed on the substrate 1 was the periodic multilayer reflective film 5 containing Mo and Si in order to make the multilayer reflective film 5 suitable for EUV light having a wavelength of 13.5 nm. The multilayer reflective film 5 was formed using a Mo target and a Si target by alternately building up a Mo film and a Si film on the substrate 1 by an ion beam sputtering method with a Kr gas atmosphere. First, a Si film was formed so as to have a thickness of 4.2 nm, and subsequently a Mo film was formed so as to have a thickness of 2.8 nm. This stack of a Si film and a Mo film was counted as one period, and a Si film and a Mo film were built up for 40 periods in a similar manner. Finally, a Si film was formed so as to have a thickness of 4.0 nm to form the multilayer reflective film 5.

Next, the four substrates 1 on each of which the multilayer reflective films 5 had been formed were subjected to a heating treatment with a hot plate to reduce a film stress of the multilayer reflective film 5. Conditions (heating temperature: 200° C.) for the heating treatments are presented in Table 1.

Next, the protective film 6 made of a material containing Ru was formed on the multilayer reflective film 5 of each of the four substrates 1. The protective film 6 was formed so as to have a film thickness of 2.5 nm by a DC sputtering method using a Ru target in an Ar gas atmosphere. Through the above steps, the four substrates with a multilayer reflective film 110 were manufactured.

<<Atomic Number Density of Hydrogen in Multilayer Reflective Film 5>>

The atomic number density [atoms/nm³] of hydrogen contained in the multilayer reflective film 5 of each of the four substrates with a multilayer reflective film 110 manufactured as described above was measured by SIMS (quadrupole secondary ion mass spectrometer: PHI ADEPT-1010™, manufactured by ULVAC-PHI, Inc.). As measurement conditions, a primary ion species was Cs⁺, a primary acceleration voltage was 1.0 kV, a primary ion irradiation area was 90 μm square, a secondary ion polarity was positive, and a detection secondary ion species was [Cs—H]⁺, [Cs-D]⁺, or [Cs—He]⁺. Si was used as a standard sample. Measurement results are presented in Table 1 below.

<<Atomic Number Density of Hydrogen in Substrate 1>>

The atomic number density [atoms/cm³] of hydrogen in the substrate 1 of each of the four substrates with a multilayer reflective film 110 was measured by SIMS (quadrupole secondary ion mass spectrometer: PHI ADEPT-1010™, manufactured by ULVAC-PHI, Inc.) in a procedure similar to that in the case of the multilayer reflective film 5. Measurement results are presented in Table 1.

<Reflective Mask Blank 100>

Next, the absorber film 7 made of a material containing TaBN was formed on the protective film 6 of each of the four substrates with a multilayer reflective film 110. The absorber film 7 was formed so as to have a film thickness of 62 nm by a DC sputtering method using a TaB mixed sintering target in a mixed gas atmosphere of an Ar gas and a N₂ gas.

Element ratios of the TaBN film for Ta, B, and N were 75 atomic %, 12 atomic %, and 13 atomic %, respectively. A refractive index n of the TaBN film at a wavelength of 13.5 nm was approximately 0.949, and an extinction coefficient k thereof was approximately 0.030.

Next, the conductive back film 2 made of CrN was formed on the second main surface (back surface) of each of the four substrates with a multilayer reflective film 110 by a DC sputtering (reactive sputtering) method under the following conditions.

Conditions for forming the conductive back film 2: a Cr target, a mixed gas atmosphere of Ar and N₂ (Ar: 90 atomic %, N: 10 atomic %), and a film thickness of 20 nm.

As described above, the four reflective mask blanks 100 each having the absorber film 7 on the protective film 6 were manufactured.

<Reflective Mask 200>

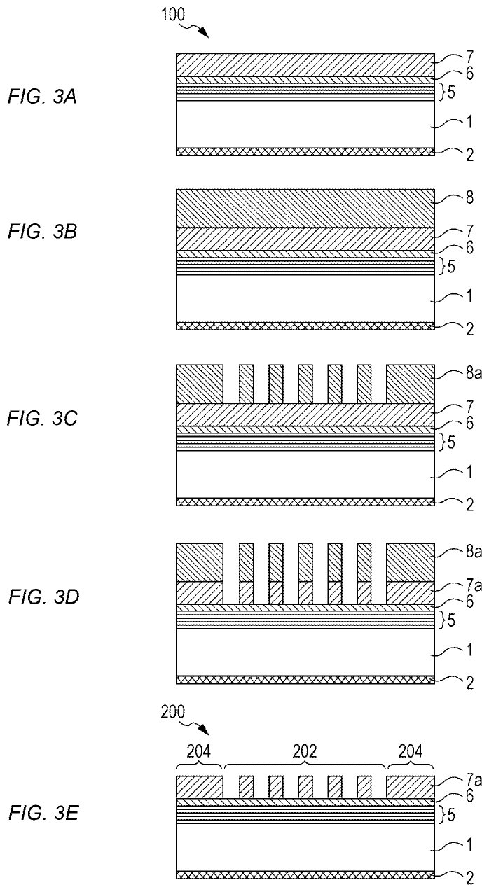

Next, using the above-described four reflective mask blanks 100, the reflective masks 200 were manufactured, respectively. A method for manufacturing each of the reflective masks 200 will be described with reference to FIGS. 3A-3E.

First, as illustrated in FIG. 3B, the resist film 8 was formed on the absorber film 7 of the reflective mask blank 100. Next, a desired pattern such as a circuit pattern was drawn (exposed) on the resist film 8. At this time, a pattern of the outer peripheral area 204 in which the multilayer reflective film 5 was irradiated with a laser beam in a subsequent step was also drawn (exposed). Next, the resist film 8 was developed and rinsed to form the predetermined resist pattern 8a (FIG. 3C). Next, using the resist pattern 8a as a mask, the absorber film 7 (TaBN film) was dry-etched using a Cl₂ gas to form the absorber pattern 7a (FIG. 3D). The protective film 6 made of a material containing Ru has extremely high dry etching resistance to a Cl₂ gas, and serves as a sufficient etching stopper. Thereafter, the resist pattern 8a was removed by ashing, a resist peeling liquid, or the like. Next, the multilayer reflective film 5 in the outer peripheral area 204 from which the absorber film 7 had been removed was irradiated with a CO₂ laser beam from above the protective film 6, and a constituent element (Mo) of the low refractive index layer and a constituent element (Si) of the high refractive index layer in the multilayer reflective film 5 were mixed to form a mixed area. Through the above steps, the four reflective masks 200 were manufactured (FIG. 3E).

The four reflective masks 200 manufactured as described above each have an area 202 having a size of 132 mm×132 mm including the absorber pattern 7a (thin film pattern) and the outer peripheral area 204 of the area 202 on the first main surface. The outer peripheral area 204 is an area where the absorber pattern 7a is not formed, and the multilayer reflective film 5 in the area forms a mixed area in which a constituent element (Mo) of the low refractive index layer and a constituent element (Si) of the high refractive index layer are mixed. When a reflectance of the multilayer reflective film 5 (in a state in which the protective film 6 is layered on the multilayer reflective film 5) in the outer peripheral area 204 of each of the four reflective masks 200 with respect to EUV light having a wavelength of 13.5 nm was measured, the reflectance was 0.7% or less in each of the cases. When a reflectance in the area 202 including the absorber pattern 7a of each of the four reflective masks 200 with respect to EUV light having a wavelength of 13.5 nm was measured, the reflectance was 67% or more in each of the cases.

TABLE 1

| | Atomic number | Time for | Atomic | |
|---|---|---|---|---|
| | density of | annealing | number | Swelling, |
| | hydrogen in | multilayer | density | peeling, or |
| | multilayer | reflective film | of hydrogen | rupture of |
| | reflective film | (200° C.) | in substrate | protective |
| | [atoms/nm³] | [min] | [atoms/cm³] | film |
| Example 1 | 0.0059 | 10 | 1.2 × 10¹⁹ | Not |
| | | | | observed |
| Example 2 | 0.0063 | 15 | 3.2 × 10¹⁹ | Not |
| | | | | observed |
| Example 3 | 0.0068 | 30 | 4.1 × 10¹⁹ | Not |
| | | | | observed |
| Comparative | 0.0075 | 60 | 2.2 × 10¹⁹ | Observed |
| Example 1 | | | | |

As can be seen from the results presented in Table 1, the reflectance of the multilayer reflective film 5 in the outer peripheral area 204 was sufficiently lower than the reflectance of the absorber pattern 7a in the area (area 202) where the pattern was formed.

As a result of observing a cross section of the reflective mask 200 with an electron microscope, in the reflective masks of Examples 1 to 3, no swelling or peeling was observed between the multilayer reflective film and the protective film. In addition, a phenomenon such as rupture of the protective film itself was not observed.

Meanwhile, in the reflective mask of Comparative Example 1, a phenomenon was confirmed in which hydrogen was accumulated between the multilayer reflective film and the protective film to cause swelling. In addition, a phenomenon was also confirmed in which the protective film itself was ruptured.

### REFERENCE SIGNS LIST

1 Substrate
2 Conductive back film
5 Multilayer reflective film
6 Protective film
7 Absorber film
7a Absorber pattern
8 Resist film
8a Resist pattern
100 Reflective mask blank
110 Substrate with a multilayer reflective film
200 Reflective mask

1. A substrate with a multilayer reflective film, comprising the multilayer reflective film and a protective film in this order on a main surface of the substrate, wherein
the substrate comprises silicon, titanium, and oxygen as main components, and further comprises hydrogen,
the multilayer reflective film has a structure in which a low refractive index layer and a high refractive index layer are alternately layered, and
the multilayer reflective film comprises hydrogen, and the hydrogen in the multilayer reflective film has an atomic number density of 7.0×10⁻³ atoms/nm³ or less.

2. The substrate with a multilayer reflective film according to claim 1, wherein the high refractive index layer comprises silicon, and the low refractive index layer comprises molybdenum.

3. The substrate with a multilayer reflective film according to claim 1, wherein hydrogen in the substrate has an atomic number density of 1.0×10¹⁹ atoms/cm³ or more, the atomic number density being obtained by performing analysis on the substrate by secondary ion mass spectrometry.

4. The substrate with a multilayer reflective film according to claim 1, wherein the protective film comprises ruthenium.

5. The substrate with a multilayer reflective film according to claim 1, wherein the multilayer reflective film has a mixed area in which a constituent element of the low refractive index layer and a constituent element of the high refractive index layer are mixed on a main surface, and a surface reflectance of the mixed area with respect to EUV light is lower than a surface reflectance of the other area with respect to EUV light.

6. A mask blank comprising a multilayer reflective film, a protective film, and a pattern forming thin film in this order on a main surface of a substrate, wherein
the substrate comprises silicon, titanium, and oxygen as main components, and further comprises hydrogen,
the multilayer reflective film has a structure in which a low refractive index layer and a high refractive index layer are alternately layered, and
the multilayer reflective film comprises hydrogen, and the hydrogen in the multilayer reflective film has an atomic number density of 7.0×10⁻³ atoms/nm³ or less.

7. The mask blank according to claim 6, wherein the high refractive index layer comprises silicon, and the low refractive index layer comprises molybdenum.

8. The mask blank according to claim 6, wherein hydrogen in the substrate has an atomic number density of 1.0×10¹⁹ atoms/cm³ or more, the atomic number density being obtained by performing analysis on the substrate by secondary ion mass spectrometry.

9. The mask blank according to claim 6, wherein the protective film comprises ruthenium.

10. The mask blank according to claim 6, wherein the multilayer reflective film has a mixed area in which a constituent element of the low refractive index layer and a constituent element of the high refractive index layer are mixed on a main surface, and a surface reflectance of the mixed area with respect to EUV light is lower than a surface reflectance of the pattern forming thin film with respect to EUV light.

11. A reflective mask comprising a multilayer reflective film, a protective film, and a thin film pattern in this order on a main surface of a substrate, wherein
the substrate comprises silicon, titanium, and oxygen as main components, and further comprises hydrogen,
the multilayer reflective film has a structure in which a low refractive index layer and a high refractive index layer are alternately layered,
the multilayer reflective film comprises hydrogen, and the hydrogen in the multilayer reflective film has an atomic number density of 7.0×10⁻³ atoms/nm³ or less, and
the multilayer reflective film has a mixed area in which a constituent element of the low refractive index layer and a constituent element of the high refractive index layer are mixed in an outer peripheral area of an area where a thin film pattern is formed on a main surface, and a surface reflectance of the mixed area with respect to EUV light is lower than a surface reflectance of the thin film pattern with respect to EUV light.

12. The reflective mask according to claim 11, wherein the high refractive index layer comprises silicon, and the low refractive index layer comprises molybdenum.

13. The reflective mask according to claim 11, wherein hydrogen in the substrate has an atomic number density of 1.0×10¹⁹ atoms/cm³ or more, the atomic number density being obtained by performing analysis on the substrate by secondary ion mass spectrometry.

14. The reflective mask according to claim 11, wherein the protective film comprises ruthenium.

15. A method for manufacturing a semiconductor device, the method comprising exposure-transferring a transfer pattern onto a resist film on a semiconductor substrate using the reflective mask according to claim 11.

16. The mask blank according to claim 7, wherein hydrogen in the substrate has an atomic number density of 1.0×10¹⁹ atoms/cm³ or more, the atomic number density being obtained by performing analysis on the substrate by secondary ion mass spectrometry.

17. The mask blank according to claim 16, wherein the protective film comprises ruthenium.

18. The mask blank according claim 17, wherein the multilayer reflective film has a mixed area in which a constituent element of the low refractive index layer and a constituent element of the high refractive index layer are mixed on a main surface, and a surface reflectance of the mixed area with respect to EUV light is lower than a surface reflectance of the pattern forming thin film with respect to EUV light.

19. The reflective mask according to claim 12, wherein hydrogen in the substrate has an atomic number density of 1.0×10¹⁹ atoms/cm³ or more, the atomic number density being obtained by performing analysis on the substrate by secondary ion mass spectrometry.

20. The reflective mask according to claim 19, wherein the protective film comprises ruthenium.
